(19) United States
(12) Patent Application Publication
(10) Pub. No.: US 2022/0399297 A1
(43) Pub. Date: Dec. 15, 2022

(54) TERMINAL STRUCTURE AND WIRING SUBSTRATE

(71) Applicant: SHINKO ELECTRIC INDUSTRIES CO., LTD., Nagano-shi (JP)

(72) Inventor: Yoko NAKABAYASHI, Nagano-shi (JP)

(21) Appl. No.: 17/833,199

(22) Filed: Jun. 6, 2022

(30) Foreign Application Priority Data
Jun. 11, 2021 (JP) 2021-097771

(51) Int. Cl. H01L 23/00; H01L 23/498

(52) U.S. Cl. CPC H01L 24/13; H01L 24/16; H01L 23/49816; H01L 23/49838; H01L 23/49822; H01L 2924/381; H01L 2924/3841; H01L 24/73; H01L 24/32; H01L 2224/73204; H01L 2224/32225; H01L 2224/11849; H01L 2224/11462; H01L 2224/11622; H01L 2224/16227; H01L 2224/16238; H01L 2224/13147; H01L 2224/13583; H01L 2224/13541; H01L 2224/13553; H01L 2224/13576; H01L 24/11; H01L 21/4853

(57) ABSTRACT

A terminal structure includes a first wiring layer, an insulation layer covering the first wiring layer, an opening extending through the insulation layer and partially exposing the first wiring layer, a via wiring formed in the opening, a second wiring layer connected to the via wiring on the insulation layer, a protective metal layer on the second wiring layer, a solder layer covering the protective metal layer, and an intermetallic compound layer formed at an interface of the protective metal layer and the solder layer. The protective metal layer includes a projection projecting further outward from a side surface of the second wiring layer. The solder layer covers upper and side surfaces of the protective metal layer through the intermetallic compound layer and exposes a side surface of the second wiring layer. The intermetallic compound layer covers the upper and side surfaces of the protective metal layer.

### CROSS-REFERENCE TO RELATED APPLICATIONS

This application is based upon and claims the benefit of priority from prior Japanese Patent Application No. 2021-097771, filed on Jun. 11, 2021, the entire contents of which are incorporated herein by reference.

### FIELD

This disclosure relates to a terminal structure, a wiring substrate, and a method for manufacturing a terminal structure.

### BACKGROUND

Wiring substrates for mounting electronic components, such as semiconductor elements, are available in various shapes and structures. Japanese Laid-Open Patent Publication No. 2020-188139 describes a wiring substrate including a solder layer formed on connection pads and used for connection of a semiconductor element.

### SUMMARY

The sophistication of semiconductor elements has narrowed the pitch between connection pads on a wiring substrate. The narrowed pitch of connection pads has resulted in adjacent portions of the solder layer becoming prone to short-circuiting subsequent to a reflow process.

One embodiment of this disclosure is a terminal structure including a first wiring layer, an insulation layer covering the first wiring layer, an opening extending through the insulation layer in a thickness-wise direction and partially exposing an upper surface of the first wiring layer, a via wiring formed in the opening, a second wiring layer electrically connected to the via wiring and formed on an upper surface of the insulation layer, a protective metal layer formed on an upper surface of the second wiring layer, a solder layer covering the protective metal layer, and an intermetallic compound layer formed at an interface of the protective metal layer and the solder layer. The protective metal layer includes a projection projecting further outward from a position corresponding to a side surface of the second wiring layer. The solder layer covers an upper surface and a side surface of the protective metal layer through the intermetallic compound layer and exposes a side surface of the second wiring layer. The intermetallic compound layer covers the upper surface and the side surface of the protective metal layer.

### BRIEF DESCRIPTION OF THE DRAWINGS

The embodiments, together with objects and advantages thereof, may best be understood by reference to the following description of the presently preferred embodiments together with the accompanying drawings in which:

FIG. 1 is a schematic cross-sectional view of a wiring substrate in accordance with an embodiment;

FIG. 2 is a partially enlarged cross-sectional view of the wiring substrate illustrated in FIG. 1;

FIG. 3 is a schematic cross-sectional view of a semiconductor device including the wiring substrate illustrated in FIG. 1;

FIG. 4 is a partially enlarged cross-sectional view of the semiconductor device illustrated in FIG. 3;

FIGS. 5A, 5B, 6A, 6B, 7A, 7B, 8A, 8B, 9A, 9B, and 10 are schematic cross-sectional views illustrating a method for manufacturing the wiring substrate illustrated in FIG. 1; and

FIG. 11 is a schematic cross-sectional view illustrating a modified example of the wiring substrate.

### DESCRIPTION OF THE EMBODIMENTS

One embodiment will now be described with reference to the drawings.

In the drawings, elements are illustrated for simplicity and clarity and have not necessarily been drawn to scale. To facilitate understanding, hatching lines may not be illustrated or be replaced by shadings in the cross-sectional drawings.

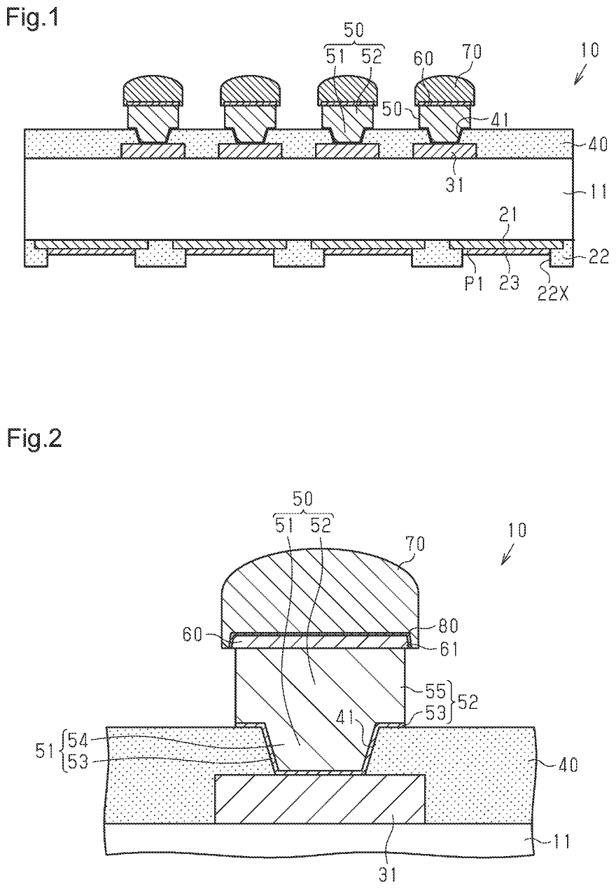

In this specification, plan view refers to a view taken in a vertical direction (e.g., vertical direction as viewed in FIG. 1), and a planar shape refers to a shape of a subject as viewed in the vertical direction. Further, in this specification, vertical and horizontal directions refer to directions that allow for the reference characters denoting members to be read with ease. Also, in this specification, the terms of parallel, orthogonal, and horizontal are not meant to be strictly parallel, orthogonal, and horizontal and include generally parallel, orthogonal, and horizontal states allowing the advantages of the embodiments to be obtained.

Configuration of Entire Wiring Substrate 10

As illustrated in FIG. 1, the wiring substrate 10 includes a main substrate body 11. A wiring layer 21 and a solder resist layer 22 are formed in order on the lower surface of the main substrate body 11. A wiring layer 31, an insulation layer 40, connection terminals 50, a protective metal layer 60, and a solder layer 70 are formed in order on the upper surface of the main substrate body 11.

A wiring structure of alternately stacked insulative resin layers and wiring layers may be used as the main substrate body 11. The wiring structure may include a cored substrate but does not have to include a cored substrate. The material of the insulative resin layers may be, for example, an insulative thermosetting resin. The insulative thermosetting resin may be, for example, an insulative resin such as an epoxy resin, a polyimide resin, or a cyanate resin. Alternatively, the material of the insulative resin layers may be, for example, an insulative resin of which the main component is a photosensitive resin such as a phenolic resin or a polyimide resin. The insulative resin layers may include, for example, a filler of silica or alumina.

The material of the wiring layers in the main substrate body 11 and the material of the wiring layers 21 and 31 may be, for example, copper (Cu) or a copper alloy. The material of the solder resist layer 22 may be, for example, an insulative resin of which the main component is a photosensitive resin such as a phenolic resin or a polyimide resin. The solder resist layer 22 may include, for example, a filler of silica or alumina.

Structure of Wiring Layer 21

The wiring layer 21 is formed on the lower surface of the main substrate body 11. The wiring layer 21 is the lowermost wiring layer of the wiring substrate 10.

Structure of Solder Resist Layer 22

The solder resist layer 22 is formed on the lower surface of the main substrate body 11 so as to cover the wiring layer 21. The solder resist layer 22 is the outermost insulation layer (here, lowermost insulation layer) of the wiring substrate 10.

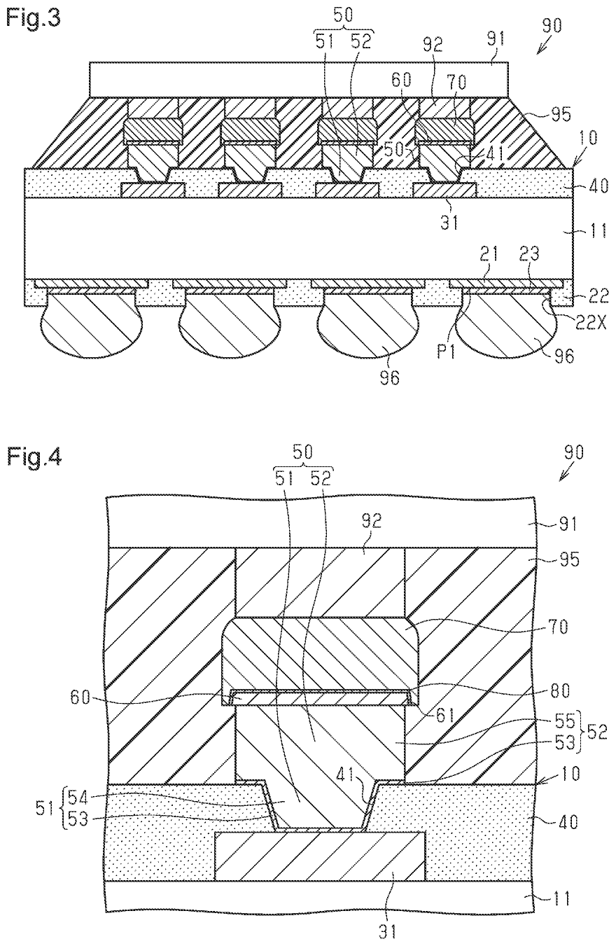

The solder resist layer 22 includes openings 22X partially exposing the lower surface of the wiring layer 21 as external connection pads P1. The external connection pads P1 are used for connection of external connection terminals 96 (refer to FIG. 3). The external connection terminals 96 are used to mount the wiring substrate 10 on a mounting substrate such as a motherboard.

When necessary, a surface treatment layer 23 is formed on the lower surface of the wiring layer 21 exposed from the openings 22X. Examples of the surface treatment layer 23 include a metal (Au) layer, a nickel (Ni) layer/Au layer (metal layer in which Ni layer serves as bottom layer, and Au layer is formed on Ni layer), Ni layer/palladium (Pd) layer/Au layer (metal layer in which Ni layer serves as bottom layer, and Ni layer and Pd layer are formed in order on Au layer). Further examples of the surface treatment layer 23 include Ni layer/Pd layer (metal layer in which Ni layer serves as bottom layer, and Pd layer is formed on Ni layer), Pd layer/Au layer (metal layer in which Pd layer serves as bottom layer, and Au layer is formed on Pd layer). An Au layer is a metal layer formed from Au or an Au alloy, an Ni layer is a metal layer formed from Ni or an Ni alloy, and a Pd layer is a metal layer formed from Pd or a Pd alloy. The Au layer, Ni layer, and Pd layer may be, for example, a metal layer formed through an electroless plating process (electroless plating layer) or a metal layer formed through an electrolytic plating process (electrolytic plating layer). Further, the surface treatment layer 23 may be an organic solderability preservative (OSP) film formed by performing an oxidation-resisting process on the lower surface of the wiring layer 21 exposed from the openings 22X. The OSP film may be, for example, an organic coating of an azole compound or an imidazole compound. When the surface treatment layer 23 is formed on the lower surface of the wiring layer 21, the surface treatment layer 23 functions as the external connection pads P1.

The external connection terminals 96 on the surface treatment layer 23 may be omitted in the example of FIG. 3. In this case, for example, the wiring layer 21 exposed from the openings 22X may be used as external connection terminals. Alternatively, when the surface treatment layer 23 is formed on the wiring layer 21, the surface treatment layer 23 may be used as external connection terminals.

Structure of Wiring Layer 31

The wiring layer 31 is formed on the upper surface of the main substrate body 11. The wiring layer 31 is electrically connected to the wiring layer 21 through an internal wiring structure (wiring layer, through-electrodes, and the like) of the main substrate body 11.

Structure of Insulation Layer 40

The insulation layer 40 is formed on the main substrate body 11 so as to partially cover the wiring layer 31. The insulation layer 40 is the outermost insulation layer (here, uppermost insulation layer) of the wiring substrate 10. The insulation layer 40 may be formed from the same material as the insulative resin layers used in the main substrate body 11. Further, the insulation layer 40 may be a solder resist layer. The solder resist layer may be formed from, for example, the same material as the solder resist layer 22. The insulation layer 40 has a thickness from the upper surface of the wiring layer 31 to the upper surface of the insulation layer 40 of, for example, approximately 4 μm to 30 μm.

The insulation layer 40 includes openings 41 extending through the insulation layer 40 in the thickness-wise direction and partially exposing the upper surface of the wiring layer 31. The openings 41 may have any shape and size in plan view. For example, the openings 41 are circular in plan view. The openings 41 have a depth of, for example, approximately 4 μm to 30 μm. Each opening 41 is tapered so that the opening width (opening diameter) increases from the lower side as viewed in FIG. 1 (side closer to wiring layer 31) toward the upper side.

Each opening 41 is defined by, for example, a wall surface forming a slope that extends from the upper surface of the insulation layer 40 and becomes closer to the center of the opening 41 in plan view as the wiring layer 31 becomes closer. The wall surface of the opening 41 does not have to be straight and may be partially or entirely convex or concave.

Structure of Connection Terminal 50

Referring to FIG. 2, each connection terminal 50 is formed on a portion of the wiring layer 31 that is exposed from one of the openings 41. The connection terminal 50 functions as, for example, an electronic component mounting pad electrically connected to an electronic component. The connection terminal 50 includes, for example, a via wiring 51 that is formed in the corresponding opening 41 and a wiring layer 52 that is electrically connected to the wiring layer 31 by the via wiring 51 and formed on the upper surface of the insulation layer 40. The connection terminal 50 may have any shape and size in plan view. For example, the connection terminal 50 is circular in plan view.

The opening 41 is, for example, filled with the via wiring 51. The via wiring 51 may be shaped in conformance with the opening 41. The wiring layer 52 has, for example, the form of a post extending upward from the upper surface of the insulation layer 40. The wiring layer 52 is formed integrally with the via wiring 51.

The connection terminal 50 includes a seed layer 53 that covers the wall surface of the opening 41 and the upper surface of the insulation layer 40. The seed layer 53, for example, continuously covers the upper surface of the insulation layer 40, the entire wall surface of the opening 41, and the entire bottom surface of the opening 41. The material of the seed layer 53 may be, for example, copper or a copper alloy. The seed layer 53 may be, for example, an electroless plating metal layer formed through an electroless plating process.

The connection terminal 50 includes a metal layer 54 that is formed on the seed layer 53 in the opening 41 and fills the opening 41. The material of the metal layer 54 may be copper or a copper alloy. The metal layer 54 may be, for example, an electrolytic plating layer formed through an electrolytic plating process. The via wiring 51 of the connection terminal 50 includes the seed layer 53 and the metal layer 54 that are formed in the opening 41.

The connection terminal 50 includes the seed layer 53 that is formed on the insulation layer 40 and a metal post 55 that is formed on the via wiring 51 (metal layer 54). The metal post 55 projects upward from the upper surface of the insulation layer 40. The metal post 55 has, for example, a flat upper surface. The metal post 55 is formed, for example, integrally with the metal layer 54. The metal post 55 may have any shape and size in plan view. The metal post 55 may have a diameter of, for example, approximately 15 μm to 40 μm. The metal post 55 may have a thickness of, for example, approximately 2 μm to 50 μm.

The material of the metal post 55 may be, for example, copper or a copper alloy. The metal post 55 may be, for example, an electrolytic plating layer formed through an electrolytic plating process. The wiring layer 52 of the connection terminal 50 is formed by the metal post 55 and the seed layer 53 that is formed on the upper surface of the insulation layer 40.

Structure of Protective Metal Layer 60

The protective metal layer 60 is formed on the upper surface of the wiring layer 52 (metal post 55). The protective metal layer 60 covers, for example, the entire upper surface of the wiring layer 52. The side surface of the wiring layer 52, for example, is exposed from the protective metal layer 60.

The protective metal layer 60 functions to restrict dissipation and oxidation of the metal forming the connection terminal 50 (e.g., copper). The protective metal layer 60 may be an Ni layer, an Au layer, a Ni layer/Au layer, a Ni layer/Pd layer/Au layer, an Ni layer/Pd layer, a Pd layer/Au layer, or the like. In one example, the protective metal layer 60 is an Ni layer. The protective metal layer 60 may have a thickness of, for example, 0.01 μm to 3 μm.

The protective metal layer 60 may have any shape and size in plan view. For example, the protective metal layer 60 and the connection terminal 50 have similar shapes (e.g., circular) in plan view. Further, the protective metal layer 60 is larger in size than the connection terminal 50 in plan view. For example, the protective metal layer 60 is slightly larger in size than the connection terminal 50 (wiring layer 52) in plan view. The protective metal layer 60 may have a diameter of, for example, approximately 20 μm to 50 μm in plan view.

The protective metal layer 60 includes a projection 61 projecting further outward from a position corresponding to the side surface of the wiring layer 52. The projection 61 projects outward from the wiring layer 52 in a planar direction (horizontal direction as viewed in FIG. 2) that is orthogonal to the thickness-wise direction of the wiring layer 52. The projection 61 includes a lower surface, which is the lower surface of the edge of the protective metal layer 60, exposed from the wiring layer 52. A step is formed by the side surface of the protective metal layer 60, the lower surface of the projection 61, and the side surface of the wiring layer 52.

The protective metal layer 60 has, for example, a width that decreases from the lower surface of the protective metal layer 60 toward the upper surface of the protective metal layer 60. For example, the protective metal layer 60 has the shape of a truncated cone so that the upper surface is smaller than the lower surface. The side surface of the protective metal layer 60 forms, for example, a slope that extends from the lower surface of the protective metal layer 60 and becomes closer to the center of the protective metal layer 60 in plan view as the upper surface becomes closer. The side surface of the protective metal layer 60 does not have to be straight and may be partially or entirely convex or concave.

Structure of Solder Layer 70

The solder layer 70 is formed on the upper surface of the protective metal layer 60. The solder layer 70 covers the entire upper surface of the protective metal layer 60. The solder layer 70 covers the side surface of the protective metal layer 60. For example, the solder layer 70 covers the entire side surface of the protective metal layer 60. The lower surface of the protective metal layer 60 is exposed from the solder layer 70. The lower surface of the projection 61 is exposed from the solder layer 70. In other words, the solder layer 70 is not formed on the lower surface of the projection 61. The side surface of the wiring layer 52 is exposed from the solder layer 70. In other words, the solder layer 70 is not formed on the wiring layer 52.

The upper portion of the solder layer 70 is, for example, round. The upper surface of the solder layer 70 is, for example, curved in an arcuate manner. The upper surface of the solder layer 70 is, for example, convex. The upper surface of the solder layer 70 is curved so that the protective metal layer 60 becomes higher as the center of the protective metal layer 60 becomes closer in plan view.

The material of the solder layer 70 may be eutectic solder or lead (Pb)-free solder. The lead-free solder may be tin (Sn)-silver (Ag), Sn—Cu, Sn—Ag—Cu, or Sn-bismuth (Bi) lead-free solder.

Structure of Intermetallic Compound Layer 80

An intermetallic compound layer 80 is formed at an interface (bonding interface) of the protective metal layer 60 and the solder layer 70. The intermetallic compound layer 80 is formed at a portion where the protective metal layer 60 and the solder layer 70 are bonded. In other words, the intermetallic compound layer 80 substantially bonds the protective metal layer 60 and the solder layer 70. The intermetallic compound layer 80 covers the entire upper surface of the protective metal layer 60. The intermetallic compound layer 80 covers the side surface of the protective metal layer 60. For example, the intermetallic compound layer 80 covers the entire upper surface of the protective metal layer 60. For example, the lower surface of the protective metal layer 60 is exposed from the intermetallic compound layer 80. In other words, the intermetallic compound layer 80 is not formed on the lower surface of the protective metal layer 60. The intermetallic compound layer 80 includes an exposed lower end surface located at an outer side of the side surface of the protective metal layer 60. The side surface of the wiring layer 52 is exposed from the intermetallic compound layer 80. In other words, the intermetallic compound layer 80 is not formed on the side surface of the wiring layer 52.

The intermetallic compound layer 80 is formed through, for example, reaction of the metal (e.g., Ni) forming the protective metal layer 60 with the metal (e.g., Sn) forming the solder layer 70. The intermetallic compound layer 80 is formed through, for example, reaction of the metal forming the metal post 55 (e.g., Cu) with the metal forming the protective metal layer 60 (e.g., Ni) and the metal forming the solder layer 70 (e.g., Sn). The intermetallic compound layer 80 is formed from, for example, an intermetallic compound of (Cu, Ni)₆Sn₅. The terminal structure of the wiring substrate 10 is formed by the connection terminal 50, the protective metal layer 60, the solder layer 70, and the intermetallic compound layer 80 that are described above.

The structure of a semiconductor device 90 will now be described with reference to FIGS. 3 and 4.

Configuration of Entire Semiconductor Device 90

Referring to FIG. 3, the semiconductor device 90 includes the wiring substrate 10, one or more (one in this case) semiconductor elements 91, an underfill resin 95, and the external connection terminals 96.

Structure of Semiconductor Element 91

Referring to FIGS. 3 and 4, the semiconductor element 91 includes connection terminals 92 formed on a circuit formation surface of the semiconductor element 91 (lower surface in this case). The semiconductor element 91 is flip-chip-mounted on the wiring substrate 10. Each connection terminal 92 of the semiconductor element 91 is electrically connected to a corresponding terminal structure of the wiring substrate 10. Referring to FIG. 4, the connection terminal 92 of the semiconductor element 91 is electrically connected via the solder layer 70 to the protective metal layer 60 and the connection terminal 50. This electrically connects the semiconductor element 91 via the connection terminal 92, the solder layer 70, and the protective metal layer 60 to the connection terminal 50. Here, the solder layer 70 is bonded to the protective metal layer 60 and the connection terminal 92.

The semiconductor element 91 may be, for example, a logic chip such as a central processing unit (CPU) chip or a graphics processing unit (GPU) chip. Further, the semiconductor element 91 may be, for example, a memory chip such as a dynamic random access memory (DRAM) chip, a static random access memory (SRAM), or a flash memory chip. When more than one semiconductor element 91 is mounted on the wiring substrate 10, a logic chip may be mounted in combination with a memory chip on the wiring substrate 10.

Structure of Connection Terminal 92

The connection terminals 92 may each be, for example, a metal post. Each connection terminal 92 is, for example, post-shaped and extends downward from the circuit formation surface of the semiconductor element 91. In the example illustrated in FIGS. 3 and 4, the connection terminals 92 are cylindrical. The material of the connection terminals 92 may be, for example, copper or a copper alloy. In addition to metal posts, the connection terminals 92 may be metal bumps (e.g., gold bumps).

Structure of Underfill Resin 95

The gap between the wiring substrate 10 and the semiconductor element 91 is filled with the underfill resin 95. The material of the underfill resin 95 may be, for example, an insulative resin such as an epoxy resin.

Structure of External Connection Terminal 96

Referring to FIG. 3, the external connection terminals 96 are formed on the external connection pads P1 of the wiring substrate 10. When mounting the wiring substrate 10 on, for example, a mounting substrate such as a motherboard (not illustrated), the external connection terminals 96 are electrically connected to the pads of the mounting substrate. The external connection terminals 96 may be, for example, solder balls or lead pins. In the example of FIG. 3, the external connection terminals 96 are solder balls. In the structure described above and illustrated in FIGS. 1 to 4, the wiring layer 31 is one example of a first wiring layer, and the wiring layer 52 is one example of a second wiring layer.

Method for Manufacturing Wiring Substrate 10

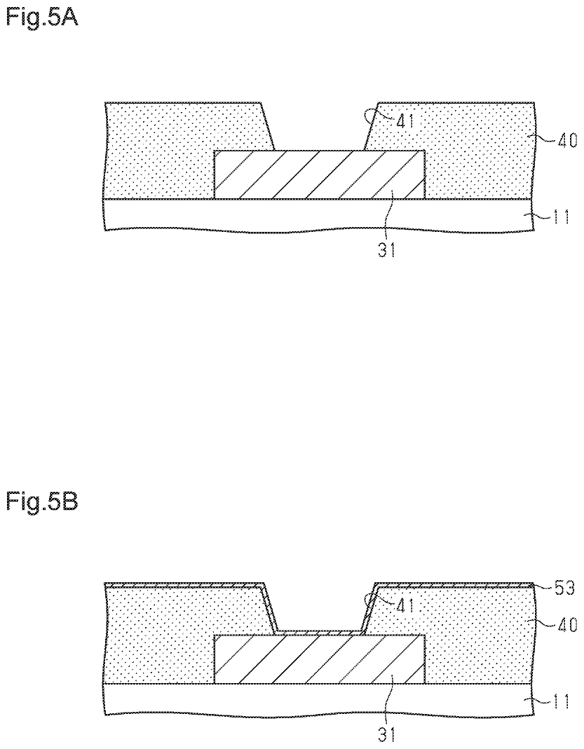

A method for manufacturing the wiring substrate 10 will now be described with reference to FIGS. 5A to 10. A method for manufacturing the terminal structure of the wiring substrate 10 will be described in detail. To simplify illustration, portions that will consequently become elements of the wiring substrate 10 are given the same reference characters as the corresponding elements in the final wiring substrate 10.

Referring to FIG. 5A, the wiring layer 31 and the insulation layer 40, which covers the wiring layer 31, are formed on the upper surface of the main substrate body 11. Then, the openings 41 are formed extending through the insulation layer 40 in the thickness-wise direction. The structure illustrated in FIG. 5A may be performed through a known manufacturing process and thus will not be described in detail.

In the following step illustrated in FIG. 5B, the seed layer 53 is formed continuously covering the entire upper surface of the insulation layer 40 and the entire wall surface of each opening 41. The seed layer 53 is formed through, for example, an electroless plating process. The seed layer 53 may be formed through an electroless copper plating process using, for example, a plating solution obtained by mixing copper sulfate, sodium hydroxide, carboxylate, nickel sulfate, and formaldehyde.

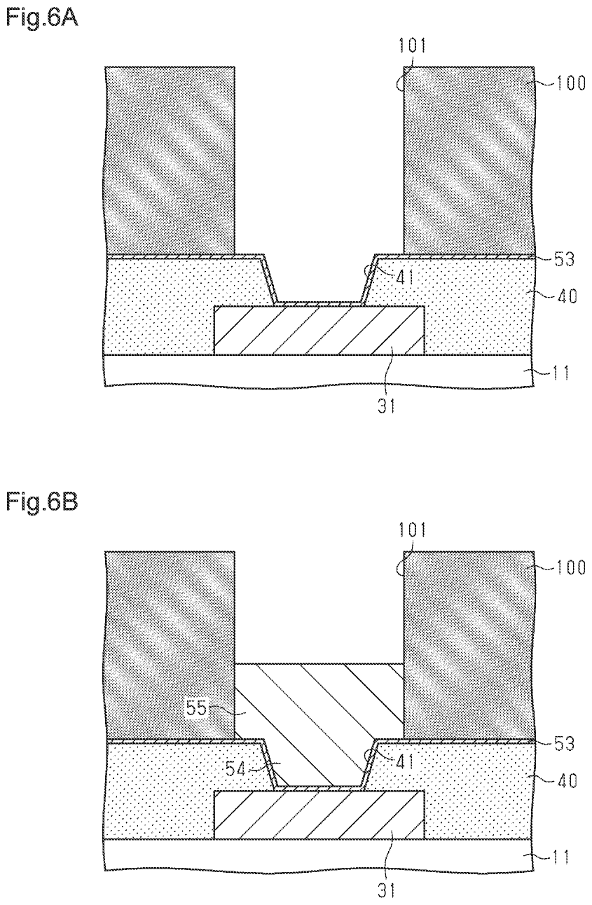

In the following step illustrated in FIG. 6A, a resist layer 100 including an opening pattern 101 is formed on the seed layer 53, which is formed on the insulation layer 40. The opening pattern 101 is formed so as to expose portions of the seed layer 53 corresponding to where each metal post 55 (refer to FIG. 2) is formed. The material of the resist layer 100 may be, for example, a material that resists plating in the electrolytic plating process performed in the following step. The resist layer 100 may be formed from, for example, a resist material such as a photosensitive dry film resist or a liquid photoresist. An example of such a resist material is a novolak resin or an acrylic resin. For example, when using a photosensitive dry film resist, thermal compression bonding is performed to laminate a dry film onto the upper surface of the seed layer 53, and a photolithography process is performed to pattern the dry film and form the resist layer 100 including the opening pattern 101. When using a liquid photoresist, the resist layer 100 may be performed through a similar process.

In the following step illustrated in FIG. 6B the upper surface of the seed layer 53 exposed from the opening pattern 101 undergoes electrolytic plating through an electrolytic plating process (e.g., electrolytic copper plating process) using the resist layer 100 as a plating mask and the seed layer 53 as a power feeding layer. As a result, each opening 41 is filled with the metal layer 54, and the metal post 55 is formed in the opening pattern 101.

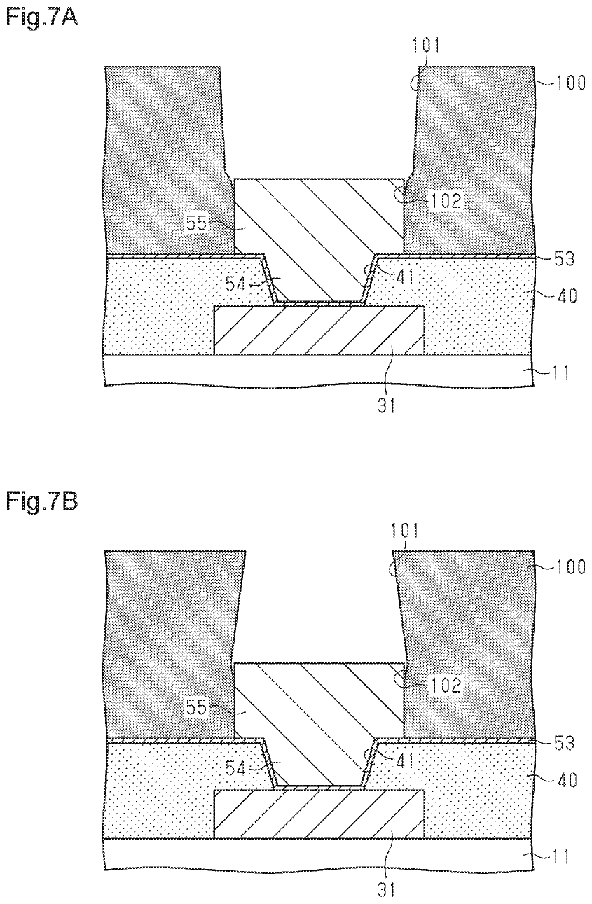

In the following step illustrated in FIG. 7A, the resist layer 100 is thinned from the inner wall surface of the opening pattern 101 to increase the opening width of the opening pattern 101. For example, the resist layer 100 is selectively scraped at the metal post 55 to thin the resist layer 100 from the inner wall surface of the opening pattern 101. This increases the width of the opening in the opening pattern 101 above the upper surface of the metal post 55 and exposes the metal post 55. As a result, the width of opening in the opening pattern 101 above the upper surface of the metal post 55 becomes slightly greater than the width of the upper surface the metal post 55.

A plasma treatment, for example, may be performed as the thinning process illustrated in FIG. 7A. Examples of plasma treatment include plasma treatment using oxygen (O₂) gas, plasma treatment using carbon tetrafluoride (CF₄) gas, and plasma treatment using O₂ gas and CF₄ gas. The plasma treatment is performed with, for example, a dry etching device. In the plasma treatment performed in the thinning process, the scraped amount increases as the upper surface of the resist layer 100 becomes closer. Thus, for example, in the opening pattern 101 subsequent to the thinning process, the opening width increases from the upper surface of the metal post 55 toward the upper surface of the resist layer 100. Further, in the plasma treatment performed in the thinning process, the scraped amount is limited at the portion of the resist layer 100 that is in contact with the side surface of the metal post 55 as compared with the portion of the resist layer 100 that is not in contact with the metal post 55. However, as illustrated in FIG. 7A, a gap 102 may be formed between the resist layer 100 and the side surface of the metal post 55 thereby partially exposing the side surface of the metal post 55.

In the following step illustrated in FIG. 7B, electrolytic plating is performed on the metal post 55 using the resist layer 100 as a plating mask and the seed layer 53 as a power feeding layer. For example, electrolytic Ni plating is performed on the metal post 55 using a plating solution obtained by mixing nickel chloride, boric acid, nickel sulfate, and the like.

Prior to electrolytic Ni plating, for example, pre-processing may be performed. Then, in the electrolytic Ni plating, the structural body obtained through the pre-processing is immersed in a plating liquid (not illustrated). The pre-processing may be an acid treatment or an alkali treatment. The resist layer 100 is formed from, for example, a material that easily swells the resist layer 100 when immersed in a plating solution or the like. The pre-processing of the resist layer 100 and the subsequent immersion of the resist layer 100 in the plating solution swells and expands the resist layer 100. For example, the resist layer 100 swells toward the inner side of the opening pattern 101. In this case, the amount of expansion increases as the upper surface of the resist layer 100 becomes closer. Thus, the opening width of the opening pattern 101 subsequent to immersion in the plating solution decreases from the upper surface of the metal post 55 toward the upper surface of the resist layer 100. Accordingly, as illustrated in FIG. 7B, the inner wall surface of the opening pattern 101 forms a slope that extends from the upper surface of the metal post 55 and becomes closer to the center of the opening pattern 101 in plan view as the upper surface of the resist layer 100 becomes closer. The inner wall surface of the opening pattern 101 does not have to be straight and may be partially or entirely convex or concave.

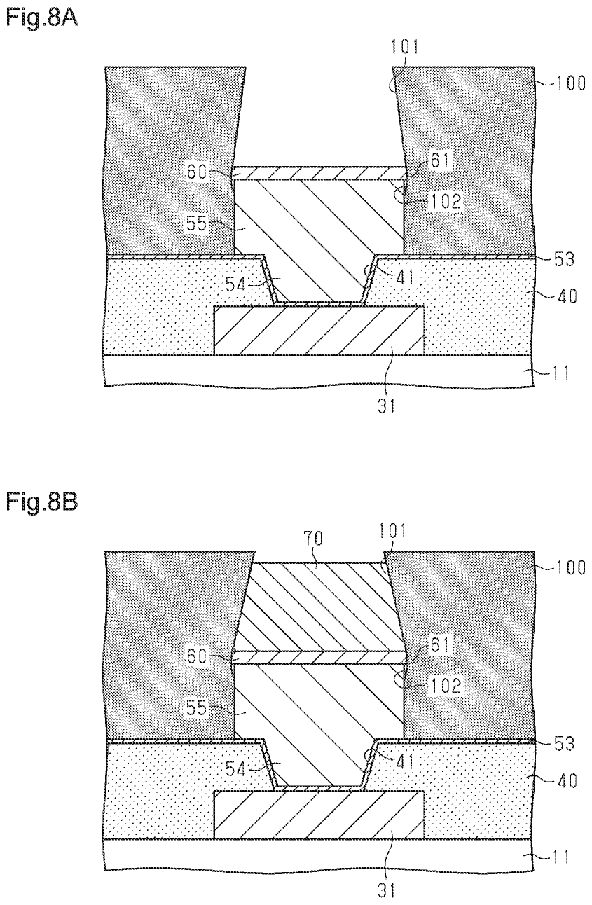

In the following step illustrated in FIG. 8A, electrolytic Ni plating is performed, using the resist layer 100 as a plating mask, to form the protective metal layer 60 on the metal post 55. The protective metal layer 60 covers the upper surface of the metal post 55. Further, the protective metal layer 60 includes the projection 61 projecting further outward from a position corresponding to the side surface of the metal post 55. When electrolytic Ni plating is performed, for example, an electrolytic Ni plating film is first deposited on the upper surface of the metal post 55. Then, further continuation of the electrolytic Ni plating deposits the electrolytic Ni plating film in an isotropic manner. As a result, the opening pattern 101 of the resist layer 100 in the vicinity of the upper surface of the metal post 55 becomes wider than the upper surface of the metal post 55. Thus, when the electrolytic Ni plating film is deposited in an isotropic manner, the protective metal layer 60 is formed projecting further outward from the side surface of the metal post 55 and toward the inner wall surface of the opening pattern 101. For example, the electrolytic Ni plating is continued until the side surface of the protective metal layer 60 comes into contact with the inner wall surface of the opening pattern 101. In this case, the side surface of the protective metal layer 60 is shaped in conformance with the inner wall surface of the opening pattern 101. Accordingly, the side surface of the protective metal layer 60 forms a slope that extends from the lower surface of the protective metal layer 60 and becomes closer to the center of the protective metal layer 60 in plan view as the upper surface of the protective metal layer 60 becomes closer.

In the following step illustrated in FIG. 8B, electrolytic solder plating is performed on the protective metal layer 60 using the resist layer 100 as a plating mask and the seed layer 53 as a power feeding layer. For example, electrolytic tin plating is performed on the upper surface of the protective metal layer 60 exposed from the opening pattern 101 of the resist layer 100 to form the solder layer 70 on the upper surface of the protective metal layer 60. In this case, prior to the formation of the solder layer 70, for example, a process for further expanding the resist layer 100 may first be performed. For example, the structural body illustrated in FIG. 8A is immersed in the plating solution to swell and further expand the resist layer 100. The resist layer 100 expands toward, for example, the inner side of the opening pattern 101. In this case, the amount of expansion increases as the upper surface of the resist layer 100 becomes closer. Thus, the opening width of the opening pattern 101 subsequent to immersion in the plating solution decreases from the upper surface of the protective metal layer 60 toward the upper surface of the resist layer 100. Accordingly, the inner wall surface of the opening pattern 101 subsequent to immersion in the plating solution forms a slope that extends from the upper surface of the protective metal layer 60 so that the center of the opening pattern 101 becomes closer in plan view as the upper surface of the resist layer 100 becomes closer. The inner wall surface of the opening pattern 101 does not have to be straight and may be partially or entirely convex or concave.

Electrolytic solder plating is continuously performed to form the solder layer 70 inside the opening pattern 101. The solder layer 70 is formed so as to fill the opening pattern 101. This forms the solder layer 70 with a shape conforming to the opening pattern 101 so that the width decreases from the lower surface of the solder layer 70 toward the upper surface of the solder layer 70. The expansion of the resist layer 100 results in the opening width of the opening pattern 101 being smaller than that prior to the formation of the protective metal layer 60. This limits spreading of the solder layer 70 in the planar direction.

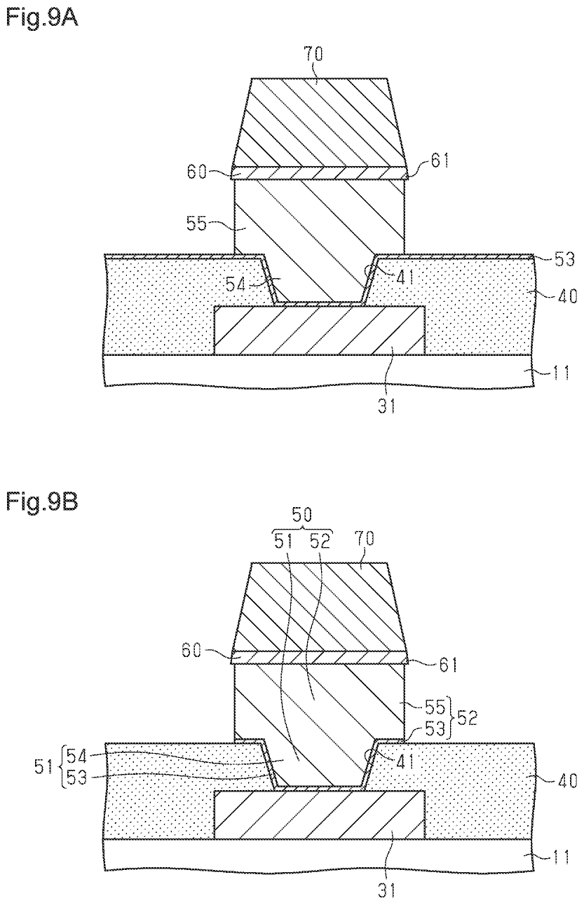

Then, the resist layer 100 is removed by an alkali delamination liquid (e.g., organic amine delamination liquid, caustic soda, or the like) or a delamination liquid of an organic solvent (e.g., acetone, ethanol, or the like). As illustrated in FIG. 9A, this exposes the upper surface of the seed layer 53 to the outside at the outer side of the metal post 55.

In the following step illustrated in FIG. 9B, etching is performed using the solder layer 70 and the metal post 55 as an etching mask to remove unnecessary portions (exposed portions) of the seed layer 53. When the seed layer 53 is an electroless plating layer, for example, wet etching is performed with a persulfate etching liquid to remove unnecessary portions of the seed layer 53. This forms the connection terminal 50 that includes the via wiring 51, which is formed in the opening 41 by the seed layer 53 and the metal layer 54, and the metal post 55, which is formed on the upper surface of the insulation layer 40 by the seed layer 53 and the wiring layer 52.

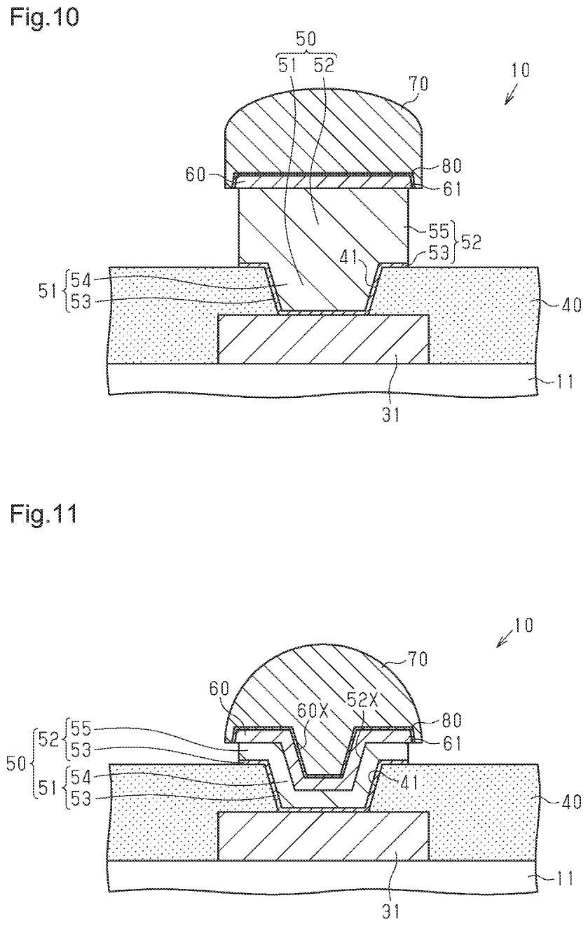

In the following step illustrated in FIG. 10, a reflow process is performed to melt the solder layer 70 and form the solder layer 70 with a round upper surface. In this step, the wet solder layer 70 spreads over the side surface of the protective metal layer 60. However, the step formed between the side surface of the protective metal layer 60 and the side surface of the metal post 55 inhibits contact of the solder layer 70 with the side surface of the metal post 55. This limits spreading of the wet solder layer 70 on the side surface of the metal post 55. The reflow process forms the intermetallic compound layer 80 at the interface of the protective metal layer 60 and the solder layer 70. The intermetallic compound layer 80 is formed on the upper surface and side surface of the protective metal layer 60 that is in contact with the solder layer 70. For example, the solder layer 70 includes Sn that reacts with Ni in the protective metal layer 60 and Cu in the metal post 55 to form the intermetallic compound layer 80 of (Cu, Ni)₆Sn₅. The process described above allows for manufacturing of the wiring substrate 10 illustrated in FIGS. 1 and 2.

The illustrated embodiment has the advantages described below.

(1) The protective metal layer 60, which is formed on the wiring layer 52, includes the projection 61 that projects further outward from a position corresponding to the side surface of the wiring layer 52. A step is formed by the side surface of the protective metal layer 60, the lower surface of the projection 61, and the side surface of the wiring layer 52. The step inhibits contact of the solder layer 70, which is arranged on the upper surface of the protective metal layer 60, with the side surface of the wiring layer 52 and limits spreading of the wet solder layer 70 on the side surface of the wiring layer 52. This avoids spreading of the solder layer 70 in the planar direction from the side surface of the wiring layer 52. As a result, short-circuiting between adjacent portions of the solder layer 70 is limited even if the pitch is narrowed between the connection terminals 50.

(2) The intermetallic compound layer 80 covers the upper surface and side surface of the protective metal layer 60. The intermetallic compound layer 80 functions to increase the strength bonding the protective metal layer 60 and the solder layer 70. Further, the intermetallic compound layer 80 functions to limit movement of the solder layer 70 when melted. Thus, the strength bonding the protective metal layer 60 and the solder layer 70 is higher than when the intermetallic compound layer 80 is arranged on only the upper surface of the protective metal layer 60. Further, the intermetallic compound layer 80 formed on the side surface of the protective metal layer 60 inhibits movement of the solder layer 70 when melted toward the side surface of the wiring layer 52.

(3) The width of the protective metal layer 60 decreases from the lower surface of the protective metal layer 60 toward the upper surface of the protective metal layer 60. Thus, the projection 61 is projected from the side surface of the wiring layer 52 by a projection amount that is the maximum at the lower end of the projection 61. This avoids contact of the solder layer 70 with the side surface of the wiring layer 52 and limits spreading of the wet solder layer 70 on the side surface of the wiring layer 52.

(4) A process for expanding the resist layer 100 is performed when forming the solder layer 70 to decrease the opening width of the opening pattern 101 in the resist layer 100. This inhibits spreading of the solder layer 70 in the planar direction and readily collects the solder layer 70 at a central portion of the protective metal layer 60 in plan view. As a result, the formation of voids in the solder layer 70 is limited.

It should be apparent to those skilled in the art that the foregoing embodiments may be implemented in many other specific forms without departing from the scope of this disclosure. Particularly, it should be understood that the foregoing embodiments may be implemented in the following forms.

The above-described embodiment and the modified examples described below may be combined as long as there is no technical contradiction.

The structure of the connection terminal 50 is not particularly limited. For example, as illustrated in FIG. 11, the via wiring 51 may be recessed and shaped in conformance with the wall surface of the opening 41. In this structure, the opening 41 is not filled with the via wiring 51. The wiring layer 52 may include a recess 52X that is recessed from the upper surface of the wiring layer 52 toward the wiring layer 31. The recess 52X may extend, for example, from the upper surface of the wiring layer 52 to a position inside the opening 41, that is, a position lower than the upper surface of the insulation layer 40. In this case, the protective metal layer 60 covers the entire upper surface of the wiring layer 52 and covers the entire wall surface in the recess 52X. The protective metal layer 60 may include a recess 60X that is recessed from the upper surface of the protective metal layer 60 toward the wiring layer 31. The recess 60X may extend, for example, from the upper surface of the protective metal layer 60 to a position inside the opening 41, that is, a position lower than the upper surface of the insulation layer 40. In the example of the structure illustrated in FIG. 11, the protective metal layer 60 also includes the projection 61 that projects further outward from a position corresponding to the side surface of the wiring layer 52. The solder layer 70, with which the recess 60X is filled with, covers, through the intermetallic compound layer 80, the entire upper surface of the protective metal layer 60 and the entire side surface of the protective metal layer 60. The intermetallic compound layer 80 covers the entire wall surface of the recess 60X, the entire upper surface of the protective metal layer 60, and the entire side surface of the protective metal layer 60.

In this structure, the wiring layer 52 includes the recess 52X, which is recessed from the upper surface of the wiring layer 52, and the protective metal layer 60 includes the recess 60X, which is recessed from the upper surface of the protective metal layer 60. Further, the solder layer 70 fills the recess 60X. Thus, the solder layer 70 is increased in volume. This allows for satisfactory bonding of the solder layer 70 and the connection terminal 50 even when the connection terminal 50 is miniaturized. Further, the solder layer 70 readily collects at a central portion of the connection terminal 50 in plan view. This limits the formation of voids in the solder layer 70. In this modified example, the recess 52X is one example of a first recess, and the recess 60X is one example of a second recess.

The structure of the protective metal layer 60 is not particularly limited. For example, the side surface of the protective metal layer 60 may extend perpendicular to the lower surface of the protective metal layer 60 in cross-sectional view. Accordingly, the side surface of the protective metal layer 60 may be a slope that extends from the upper surface of the protective metal layer 60 and becomes closer to the center of the protective metal layer 60 in plan view as the lower surface of the protective metal layer 60 becomes closer. In other words, the protective metal layer 60 may be tapered so that the width decreases from the upper surface of the protective metal layer 60 toward the lower surface of the protective metal layer 60. Even in this case, the lower end of the side surface of the protective metal layer 60 is located at an outer side of the side surface of the wiring layer 52.

In the above embodiment, the resist layer 100 is expanded before the protective metal layer 60 is formed. However, the process for expanding the resist layer 100 may be omitted.

In the above embodiment, the resist layer 100 is expanded before the solder layer 70 is formed. However, the process for expanding the resist layer 100 may be omitted.

The seed layer 53 does not have to be formed through an electroless plating process (e.g., electroless copper plating process). For example, the seed layer 53 may be formed through a sputtering process or a vapor deposition process.

The seed layer 53 does not have to be a single-layer structure and may be a multi-layer structure (e.g., double-layer structure). An example of a seed layer 53 having a double-layer structure is a stack of a titanium (Ti) layer and a Cu layer.

The solder layer 70 does not have to be formed through an electrolytic solder plating process. For example, a solder ball may be arranged on the protective metal layer 60 exposed at the bottom portion of the opening pattern 101 of the resist layer 100, and the solder ball may be melted to form the solder layer 70.

The surface treatment layer 23 may be omitted from the wiring substrate 10.

The underfill resin 95 may be omitted from the semiconductor device 90.

The external connection terminals 96 may be omitted from the semiconductor device 90.

Instead of the semiconductor element 91, an electronic component (e.g., chip component such as chip capacitor, chip resistor, chip inductor, or the like, or a crystal oscillator) may be mounted on the wiring substrate 10.

The wiring substrate 10 may be embodied in a wiring substrate for any type of package such as a chip size package (CSP) or a small outline non-lead package (SON).

### CLAUSES

This disclosure further encompasses the following embodiments.

1. A method for manufacturing a terminal structure, the method including:

forming an insulation layer that covers a first wiring layer and incudes an opening partially exposing an upper surface of the first wiring layer;

forming a seed layer that continuously covers an upper surface of the insulation layer and a wall surface of the opening;

forming a resist layer on an upper surface of the seed layer, where the resist layer includes an opening pattern;

forming a second wiring layer on the seed layer exposed from the opening pattern by performing an electrolytic plating process using the resist layer as a mask and the seed layer as a power feeding layer;

thinning the resist layer from an inner wall surface of the opening pattern to increase an opening width of the opening pattern;

forming a protective metal layer that covers an upper surface of the second wiring layer by performing an electrolytic plating process using the resist layer as a mask and the seed layer as a power feeding layer, where the protective metal layer includes a projection projecting further outward from a position corresponding to a side surface of the second wiring layer;

forming a solder layer on the protective metal layer; and

removing the resist layer.

2. The method according to clause 1, where the forming a protective metal layer includes:

expanding the resist layer to decrease the opening width of the opening pattern; and

forming the protective metal layer through an electrolytic plating process using the expanded resist layer as a mask and the seed layer as a power feeding layer.

3. The method according to clause 1 or 2, where the forming a solder layer includes:

expanding the resist layer to decrease the opening width of the opening pattern, and

forming the solder layer on an upper surface of the protective metal layer through an electrolytic solder plating process using the expanded resist layer as a mask and the seed layer as a power feeding layer.

All examples and conditional language recited herein are intended for pedagogical purposes to aid the reader in understanding the principles of the invention and the concepts contributed by the inventor to furthering the art, and are to be construed as being without limitation to such specifically recited examples and conditions, nor does the organization of such examples in the specification relate to an illustration of the superiority and inferiority of the invention. Although embodiments have been described in detail, it should be understood that various changes, substitutions, and alterations could be made hereto without departing from the scope of this disclosure.

What is claimed is:

1. A terminal structure, comprising:
a first wiring layer;
an insulation layer covering the first wiring layer;
an opening extending through the insulation layer in a thickness-wise direction and partially exposing an upper surface of the first wiring layer;
a via wiring formed in the opening;
a second wiring layer electrically connected to the via wiring and formed on an upper surface of the insulation layer;
a protective metal layer formed on an upper surface of the second wiring layer;
a solder layer covering the protective metal layer; and
an intermetallic compound layer formed at an interface of the protective metal layer and the solder layer, wherein
the protective metal layer includes a projection projecting further outward from a position corresponding to a side surface of the second wiring layer,
the solder layer covers an upper surface and a side surface of the protective metal layer through the intermetallic compound layer and exposes the side surface of the second wiring layer, and
the intermetallic compound layer covers the upper surface of the protective metal layer and the side surface of the protective metal layer.

2. The terminal structure according to claim 1, wherein:
the projection includes a lower surface exposed from the solder layer; and
the lower surface of the projection is further exposed from the intermetallic compound layer.

3. The terminal structure according to claim 1, wherein the projection is separated from an entirety of the side surface of the second wiring layer.

4. The terminal structure according to claim 1, wherein the intermetallic compound layer includes an exposed lower end surface located at an outer side of the side surface of the protective metal layer.

5. The terminal structure according to claim 1, wherein the protective metal layer has a width that decreases from a lower surface of the protective metal layer to the upper surface of the protective metal layer.

6. The terminal structure according to claim 1, wherein:
the opening is filled with the via wiring; and
the second wiring layer has the form of a post extending upward from the upper surface of the insulation layer.

7. The terminal structure according to claim 1, wherein:
the via wiring is recessed and shaped in conformance with a wall surface of the opening;
the second wiring layer includes a first recess that is recessed from the upper surface of the second wiring layer toward the first wiring layer;
the protective metal layer includes a second recess that is recessed from the upper surface of the protective metal layer toward the first wiring layer; and
the second recess is filled with the solder layer.

8. The terminal structure according to claim 7, wherein the second recess extends from the upper surface of the protective metal layer to a position lower than the upper surface of the insulation layer.

9. A wiring substrate, comprising a terminal structure according to claim 1.
